(19) United States
(12) Patent Application Publication
(10) Pub. No.: US 2025/0204134 A1
(43) Pub. Date: Jun. 19, 2025

(54) OPTOELECTRONIC DEVICE AND ASSOCIATED MANUFACTURING METHOD

(71) Applicant: COMMISSARIAT A L'ENERGIE ATOMIQUE ET AUX ENERGIES ALTERNATIVES, Paris (FR)

(72) Inventors: Carole PERNEL, Grenoble Cedex (FR); Stéphane ALTAZIN, Grenoble Cedex (FR); Etienne QUESNEL, Grenoble Cedex (FR)

(73) Assignee: COMMISSARIAT A L'ENERGIE ATOMIQUE ET AUX ENERGIES ALTERNATIVES, Paris (FR)

(21) Appl. No.: 18/984,215

(22) Filed: Dec. 17, 2024

(30) Foreign Application Priority Data
Dec. 18, 2023 (FR) 2314363

(51) Int. Cl. H10H 29/855; H01L 25/075; H10H 29/01; H10H 29/24; H10H 29/851; H10H 29/856

(52) U.S. Cl. CPC H10H 29/855; H01L 25/0753; H10H 29/0363; H10H 29/24; H10H 29/8516; H10H 29/856

(57) ABSTRACT

An optoelectronic device, comprising a stack including a plurality of light-emitting diodes disposed at a distance from one another, and a plurality of electrically conductive terminals arranged between the diodes, and a light confinement layer extending over the stack and comprising reflective walls defining between them, spaces located to the right of each diode. Further, the confinement layer includes the porous alumina in at least one of the spaces, the porous alumina having, in at least one space, preferably in at least two of the spaces, even in each space, from among the at least some spaces, at least two open pores on a first face of the confinement layer which is located opposite the stack. The optical crosstalk phenomena are advantageously reduced.

### TECHNICAL FIELD

The present invention relates to an optoelectronic device intended to equip a display screen or an image projection system. The present invention also relates to a method for manufacturing such an optoelectronic device.

### PRIOR ART

There are optoelectronic devices comprising a light-emitting diode matrix having an emission surface, at least partially coated by light colour converters. Such optoelectronic devices can form display screens or image projection systems comprising a light pixel matrix of different colours.

Light-emitting diodes can be formed with the basis of a semiconductive material comprising elements of column III and of column V of the periodic table, such as a III-V compound, in particular, gallium nitride (GaN), indium and gallium nitride (InGaN) or aluminium gallium nitride (AlGaN). They are arranged so as to form a light-emitting diode matrix having an emission surface through which the light radiation emitted by the light-emitting diodes is transmitted.

In the case of a display screen or an image projection system, the optoelectronic device can thus comprise a light pixel matrix, each light pixel comprising one or more light-emitting diodes. With the aim of obtaining light pixels emitting lights of different colours, for example, blue, green or red, the light-emitting diodes can be adapted to emit a blue light, and certain light pixels can be associated with light colour converters, such as photoluminescent terminals, adapted to absorb the blue light emitted by the light-emitting diodes, and to emit, in response, a green or red light. The photoluminescent terminals are usually formed of a binding matrix, called resin below, comprising particles of a photoluminescent material such as yttrium aluminium garnet (YAG), activated by the cerium ion YAG:Ce.

The emission of light-emitting diodes, and therefore pixels, is more or less angularly directive and optical crosstalk phenomena can be generated between pixels or between light-emitting diodes. Furthermore, the use of light colour converters, such as the photoluminescent terminals introduced above, can accentuate these optical crosstalk phenomena.

To limit these phenomena, it has been proposed to optically isolate the pixels from one another, either by adding a black matrix between the pixels, or, more advantageously, by adding side mirrors, preferably made of aluminium or silver, on flanks of the photoluminescent terminals. Methods for manufacturing said side mirrors are described in patent documents referenced FR3101130 A1, FR3061358 A1, FR3083370 A1, FR3087580 A1 and US2023/0033031 A1. More specifically, it is proposed, through these references, different techniques for manufacturing cavities above blue pixels to fill them with a quantum dot/QD-charged resin for the conversion of the blue light emitted by the pixels into a green light or into a red light. However, these techniques require numerous technological steps (SiO2 deposition, photolithography, metal deposition by atomic layer deposition (ALD), etching, dismantling, aligned transfer, etc.), making their integration complex. It is also known from the article by Siontas et al. entitled “Broadband visible-to-telecom wavelength germanium quantum dot photodetectors” and which appeared in APPLIED PHYSICS LETTERS 113, 251901 (2018), a filling of the cavities using QDs suspended in a solvent which evaporates secondly (drying) only leaving the QDs. There, it is more specifically disclosed to deposit, in the cavities of a nanoporous alumina matrix, CsPbBr3-based perovskite QDs diluted in dimethyl sulfoxide (or DMSO) as a solvent, and to heat them secondly to evaporate the dimethyl sulfoxide.

Moreover, a mesoporous layer comprising J-aggregates and quantum dots, making it possible to increase the Forster resonance energy transfer (FRET), and therefore the emission rate of an assembly comprising such a mesoporous layer is known, from patent document referenced EP2708492 B1.

An aim of the present invention is to propose an optoelectronic device, in particular intended to equip a display screen or an improved image projection system, relative to current optoelectronic devices, in particular by reducing the optical crosstalk phenomena.

An aim of the present invention is to propose such a device having a better light conversion rate. Alternatively or complementarily, an aim of the present invention is to propose such a device, the manufacturing method of which is simpler or at the very least, no more complex, than the current methods.

Another aim of the present invention is to propose an optoelectronic device and an associated manufacturing method which are a technological integration which is more immediate than the solutions of the prior art.

### SUMMARY

To achieve this aim, according to a first aspect of the invention, an optoelectronic device is provided, comprising:
a. a stack comprising:
   i. a plurality of P-N junction light-emitting diodes disposed at a distance from one another, and
   ii. a plurality of electrically conductive terminals disposed between the light-emitting diodes,
      the electrically conductive terminals being electrically isolated from at least one p or n zone of the P-N junctions of the light-emitting diodes,
b. a light confinement layer extending over a stack and comprising reflective walls defining or delimiting between them, spaces or volumes, each located to the right of at least one, preferably each, light-emitting diode.

The optoelectronic device is mainly such that the light confinement layer further comprises porous alumina in at least some of said spaces, the porous alumina having, in at least one space, preferably at least two spaces, even in each space, from among said at least some of said spaces, at least two open pores on a first face of the confinement layer which is located opposite the stack.

In order to benefit from the optical diffusion properties of the (nano) porous alumina, the pores of the porous alumina preferably have transverse dimensions of between 1 and 500 nm and preferably between 50 and 400 nm. Still in order to benefit from the optical diffusion properties of the nanoporous alumina, alternatively or complementarily to the preceding preference, the pores of the porous alumina preferably have a periodicity of between 200 and 700 nm. Thus, it is advantageously provided to have several pores above at least one, preferably above each, light-emitting diode, and therefore especially per pixel, in order to maximise the optical properties of the optoelectronic device. Also, the size of the pores is preferably greater than the dimension of the colour conversion particles that are sought to slide inside, so as to be able to have at least one colour conversion particle in each pore.

According to an example of the first aspect of the invention, the porous alumina has, in at least one space, preferably at least two spaces, even in each space, from among said at least some of said spaces, at least eight open pores on the first face of the confinement layer, which is located opposite the stack. A better extraction of the light emitted by the underlying light-emitting diode(s) is thus obtained.

According to an example of the first aspect of the invention, alternative to the preceding example, the porous alumina has, in at least one space, preferably at least two spaces, even in each space, from among said at least some of said spaces, at least one pore every 2×λ, where λ represents the wavelength to be extracted and at least four pores per space (1 μm pixel case).

According to an example of the first aspect of the invention, at least one, preferably each, open pore on the first face of the confinement layer which is located opposite the stack, has a filling rate, made of the light colour conversion material, substantially equal to 30%. The colour conversion rate is thus optimised. More specifically, with respect to the prior art which consists of an Al2O3 pore above an LED, the conversion rate obtained in this case is better.

According to a second aspect of the invention, a method for manufacturing an optoelectronic device is provided, the method comprising the following steps:
a. providing a stack comprising:
   i. a plurality of P-N junction light-emitting diodes disposed at a distance from one another, and
   ii. a plurality of electrically conductive terminals disposed between the light-emitting diodes,
      the electrically conductive terminals being electrically isolated from at least one p or n zone of the P-N junctions of the light-emitting diodes,
b. forming, on the stack, a light confinement layer comprising reflective walls defining or delimiting between them, spaces or volumes, each located to the right of at least one, preferably each, light-emitting diode, by:
   i. deposition of an aluminium-based layer on a main face of the stack by which light-emitting diodes are configured to emit, then
   ii. anodising the aluminium-based layer at least outside of zones located to the right of the conductive terminals of the stack.

The method is mainly such that the anodising is configured such that the porous alumina is formed in at least some of said spaces, by having, in at least one space, preferably at least two spaces, even in each space, from among said at least some of said spaces, at least two open pores on a first face of the confinement layer which is located opposite the stack.

According to a third aspect of the invention, a display screen or system for projecting at least one image is provided, comprising at least one optoelectronic device such as introduced above.

It is thus advantageously made possible to benefit from the preferably anisotropic nature of anodising aluminium. Indeed, the optoelectronic device can comprise a space filled with the porous alumina above each light-emitting diode, and the porous alumina comprising pores having a high form factor, the confinement of the light by the confinement layer is improved, in particular by increasing the diffusion in each pore of the light emitted by the underlying light-emitting diode, and by thus reducing the optical crosstalk phenomena, beyond which only the reflective walls enable, especially when the pores of the porous alumina are filled with a light colour conversion material.

Below, it will appear that the optoelectronic device such as introduced above can be an intermediate product intended for the manufacture of a more advanced optoelectronic device. In this scope, it is noted that the porous alumina filling the space above each light-emitting diode has, at the very least, the advantage of easily enabling the deep and anisotropic etching of this space.

By considering the optoelectronic device such as introduced above as an intermediate product, it is also advantageously made possible, thanks to this intermediate product, to manufacture further improved optoelectronic devices, or more easily, relative to the current one.

### BRIEF DESCRIPTION OF THE FIGURES

The aims, objective, as well as the features and advantages of the invention will best emerge from the detailed description of an embodiment of the latter, which is illustrated by the following accompanying drawings, in which:

FIG. 1 represents a cross-sectional view of a part of an optoelectronic device according to a first embodiment of the invention or an intermediate product making it possible to obtain an optoelectronic device according to the second embodiment represented in FIG. 2.

FIG. 2 represents a cross-sectional view of a part of an optoelectronic device according to a second embodiment of the invention.

FIG. 3 represents a cross-sectional view of a part of an optoelectronic device according to a third embodiment of the invention or an intermediate product making it possible to obtain an optoelectronic device according to the fourth embodiment represented in FIG. 4.

FIG. 4 represents a cross-sectional view of a part of an optoelectronic device according to a fourth embodiment of the invention.

FIG. 5 represents a cross-sectional view of a part of an optoelectronic device according to a variant of the first embodiment of the invention, which is illustrated in FIG. 1.

FIG. 6 represents a cross-sectional view of a part of an optoelectronic device according to a variant of the second embodiment of the invention, which is illustrated in FIG. 2.

FIG. 7 represents a cross-sectional view of a part of an optoelectronic device according to a variant of the third embodiment of the invention, which is illustrated in FIG. 3 or an intermediate product making it possible to obtain an optoelectronic device according to a variant of the fourth embodiment, which is illustrated in FIG. 8.

FIG. 8 represents a cross-sectional view of a part of an optoelectronic device according to a variant of the third embodiment of the invention, which is illustrated in FIG. 3.

FIGS. 9 to 12 schematically illustrate steps of an embodiment of a method for manufacturing an optoelectronic device such as illustrated in FIG. 1.

FIGS. 13 to 15 schematically illustrate steps of an embodiment of a method for manufacturing an optoelectronic device such as illustrated in FIG. 5.

FIG. 16 represents a cross-sectional view of a part of an optoelectronic device according to a fifth embodiment of the invention.

FIG. 17 represents a cross-sectional view of a part of an optoelectronic device (if necessary, without the element referenced 2200) according to a first variant of the fifth embodiment of the invention, which is illustrated in FIG. 16. FIG. 17 can alternatively be seen as a step of a method for manufacturing the optoelectronic device such as illustrated in FIG. 18 from that illustrated in FIG. 16.

FIG. 18 represents a cross-sectional view of a part of an optoelectronic device according to a variant of the fifth embodiment of the invention, which is illustrated in FIG. 16.

The drawings are given as examples and are not limiting of the invention. They constitute principle schematic representations intended to facilitate the understanding of the invention and are not necessarily to the scale of practical applications. In particular, the thicknesses and other dimensions of the different layers and other elements illustrated are not necessarily representative of reality, and are not necessarily to scale.

### DETAILED DESCRIPTION

Before starting a detailed review of embodiment of the invention, optional features of the first aspect of the invention are stated below, which can optionally be used in association or alternatively:

According to an example, each of the spaces is filled with the porous alumina.

According to an example, the pores of the porous alumina form channels opening onto the first face of the confinement layer. The pores of the porous alumina thus have a significantly high form factor, so as to further increase the diffusion in each pore of the light emitted by the underlying light-emitting diode.

According to an example, the pores of the porous alumina form channels extending mainly along a direction perpendicular to the first surface of the confinement layer. The longitudinal dimensions of the pores are preferably greater than their transverse dimensions.

According to an example, at least some of the pores, preferably all the pores, have a dimension Lp by length, taken in projection along a direction perpendicular to the first face, strictly less than a thickness E12 of the confinement layer, and preferably less than 2 nm; therefore a few nm of alumina or aluminium remain at the bottom of the pores. The confinement layer can have a thickness E12 of between 500 nm and 10 μm or more.

According to an example, the pores extend substantially up to the stack, potentially without reaching it, but preferably by reaching it to not loss optical efficiency. The risk of delaminating the confinement layer from the stack is mechanically limited, because the stability of the structure can be ensured by the Al pillars not made porous above the contacts, while benefiting from an even higher form factor of the pores of the porous alumina.

According to an example, at least one pore, preferably each pore, has a form factor defined by transverse dimensions substantially between 40 nm and 800 nm, and/or a longitudinal dimension substantially between 500 nm and 10 μm or more, and preferably a longitudinal dimension substantially between 1 μm and 5 μm.

Complementarily or alternatively, the open pores on the first face of the confinement layer can occupy a surface substantially equal to 30% of the total surface of this confinement layer and/or the open pores above at least one light-emitting diode which are adjacent to one another can be distant in pairs, by their centres, by a distance substantially equal to a wavelength of the light emitted by the underlying light-emitting diode, this wavelength typically belonging to the blue light spectrum, that is for example, between 380 and 450 nm.

Thus, anodising aluminium is benefited from, being able to be configured in a known manner and controlled to ensure that the pores formed have dimensions specific to enabling their filling, in particular by different light colour conversion materials.

According to an example, the stack further comprises:
a. a carrier substrate,
b. an emissive structure matrix extending over the carrier substrate, the emissive structure matrix comprising the plurality of light-emitting diodes which extend over the carrier substrate through an interfacing (or bonding) layer and the plurality of electrically conductive terminals extending either directly over the carrier substrate, or through an electrical isolation wall. At least one, preferably each, emissive structure comprises at least one light-emitting diode and at least some of each of the adjacent electrically conductive terminals, an electrical isolation wall separating, if necessary, at least partially, the light-emitting diode and each of the adjacent electrically conductive terminals to avoid short-circuiting at least one p or n zone of the P-N junctions of the light-emitting diodes.

According to an example, at least one, preferably each, emissive structure further comprises at least one electrical isolation wall or dielectric wall, if necessary partial:
a. between at least one electrically conductive terminal and at least one adjacent light-emitting diode, and/or
b. between at least one electrically conductive terminal and the carrier substrate.

According to an example, at least one, preferably each, emissive structure further comprises dielectric walls, first dielectric walls of which extending between at least one, preferably each, conductive terminal and the interfacing layer and second dielectric walls extending over at least some of the lateral sides of each conductive terminal, the first and second dielectric terminals preferably being attached to one another, such that each conductive terminal is electrically isolated over some of its perimeter.

According to an example, the carrier substrate comprises at least one application-specific integrated circuit (ASIC), and at least one electrical connection terminal between said integrated circuit and at least one, for example more, light-emitting diode(s). Complementarily or alternatively, the stack further comprises an electrode layer with the basis of a conductive and transparent material, such as indium tin oxide (ITO), the electrode layer extending, if necessary continuously, between, on the one hand, the pluralities of light-emitting diodes and electrically conductive terminals, and on the other hand, the light confinement layer.

According to an example, at least one, potentially each, reflective wall is aluminium-based.

According to an example, at least some of an outer perimeter, in particular side, of at least one, preferably each, reflective wall is aluminium-based, or is constituted of aluminium.

According to an example, at least one electrically conductive terminal is aluminium-based, if necessary said at least one electrically conductive terminal and the reflective wall located to the right of said at least one electrically conductive terminal form a bulk volume. The electrically conductive terminals can thus be advantageously made of one same material as that with the basis of which the reflective walls are constituted, which simplifies the device and its manufacturing method, in particular by avoiding a technological step of depositing, for example, by electrodeposition, electrically conductive terminals with the basis of a metallic material other than aluminium, for example, copper-based.

According to an example, at least one, potentially each, reflective wall is porous alumina-based and with the basis of a reflective material located in the pores of the porous alumina.

According to an example, the optoelectronic device further comprises a light colour conversion material located in the pores of the porous alumina located to the right of at least one light-emitting diode, preferably to the right of each light-emitting diode. The optical crosstalk phenomena are also advantageously reduced. According to this example, the light colour conversion material is grafted to the internal walls of the pores. Thus, the surface/conversion particle interactions are strong and the filling of the pores with the particles is improved. Furthermore, the grafting of the conversion particles on the internal walls of the pores makes it possible for the conversion particles to better resist the flow, which potentially ensures a better resistance to ageing of the optoelectronic device.

According to an example, the light colour conversion material is located in, and if necessary filled, at least one, for example at least some, preferably, each of the pores (or channels) formed by the porous alumina.

According to an example, the light confinement layer has no porous alumina in at least one, potentially more, of said spaces.

According to the preceding example, at least one, preferably each, space with no porous alumina is filled with a light colour conversion material. It is thus possible to design an optoelectronic device having different configurations of its confinement layer according to the light-emitting diode considered or the group of light-emitting diodes considered, said group being able, in particular, to constitute a pixel. The optoelectronic device proposed therefore advantageously has a modularity in this regard.

According to an example, the light colour conversion material comprises at least one from among:
a. quantum dots,
b. J-aggregates,
c. phosphorescent (or fluorescent) nanoparticles, and
d. perovskites,
   if necessary, put in a solution in a solvent or incorporated in a resin. Advantageously, the different light colour conversion materials usually used in the field of display screens and other image projection systems can be inserted in the pores of the porous alumina, and therefore can be used in the scope of the present invention.

According to an example, the light colour conversion material filling at least one, preferably each, space with no porous alumina comprises at least one chosen from among:
a. quantum dots, and
b. J-aggregates.

According to an example, the light-emitting diodes are configured to emit a light of a determined first wavelength, for example, blue colour, along a direction substantially parallel to the first face of the confinement layer.

Complementarily or alternatively, the light colour conversion material is specific to converting the light emitted at the first wavelength into a light having a second wavelength different from the first, for example, the first wavelength being located in blue and the second wavelength being located in one from among green and red.

It is understood that the optional features stated above can each qualify, alternatively to the first aspect of the invention such as introduced above, an optoelectronic device comprising:
a. a stack comprising:
   i. a plurality of light-emitting diodes disposed at a distance from one another, and
   ii. a plurality of electrically conductive terminals disposed between the light-emitting diodes,
b. a light confinement layer extending over the stack and comprising reflective walls, defining or delimiting between them, spaces or volumes, each located to the right of a light-emitting diode.

Optional features of the second aspect of the invention are stated below, which can optionally be used in association or alternatively:

According to an example, the aluminium-based layer is deposited so as to have a thickness substantially of between 500 nm and 10 μm, preferably substantially of between 1 and 6 μm.

According to an example, the step of anodising the aluminium-based layer is configured such that the porous alumina forms channels opening through the open pores on the first face of the confinement layer, and preferably such that at least one channel, for example, each channel, has transverse dimensions substantially of between 40 nm and 800 nm, and/or a longitudinal dimension substantially of between 500 nm and 10 μm, preferably substantially of between 1 and 6 μm.

According to an example, the step of anodising the aluminium-based layer is configured such that at least some of the pores (or channels) have a dimension Lp by length, taken in projection along a direction perpendicular to the first face, strictly greater than half of a thickness E12 of the confinement layer.

According to an example, the step of anodising the aluminium-based layer is configured such that at least some of the pores (or channels) have a dimension Lp by length, taken in projection along a direction perpendicular to the first face, at most equal, and preferably strictly less, for example by 2 nm, than a thickness of the aluminium-based layer. Thus, the risk of delaminating the confinement layer from the stack is limited.

According to an example, the method further comprises, following the deposition of the aluminium layer and before its anodising:
a. depositing a mask on zones of the aluminium-based layer which are located substantially to the right of the conductive terminals of the stack, the mask having openings located to the right of the light-emitting diodes,
   the anodising of the aluminium-based layer being carried out through the openings of the deposited mask. The mask can be silicon oxide- or silicon nitride (SiN)-based.

According to an example, the step consisting of providing the stack comprises the deposition, between the light-emitting diodes, of aluminium to form at least some of the plurality of electrically conductive terminals of the stack and this deposition step is extended to carry out the deposition of the aluminium-based layer. In this way, the formation of the electrically conductive terminals and the formation of the aluminium layer can be implemented in one same technological aluminium deposition step.

According to an example, the manufacturing method further comprises the deposition of a light colour conversion material in the pores of the porous alumina, at the at least one, preferably some, for example each, of said spaces. According to this example, the conversion material and/or the internal walls of the pores are functionalised, before the deposition of the light colour conversion material in the pores of the porous alumina, so as to obtain a grafting to one another, for example, by surface-OH bonds, created if necessary, by a treatment with an alkaline chemistry or by a dry plasma treatment or by adsorption of a ligand.

According to an example, alternative to the preceding example, the manufacturing method comprises the removal, for example, by etching, of the porous alumina at the at least one, for example some, of said spaces, and the filling of at least one of the spaces thus removed with a light colour conversion material. Thus, both the known possibility of selectively etching the porous alumina relative to the aluminium and the anisotropic nature of anodising the aluminium are benefited from, to obtain flat, reflective walls which are substantially perpendicular, relative to the face of the stack through which the light-emitting diodes are configured to emit.

According to an example, the anodising step comprising the anodising of some of the aluminium-based layer which is located to the right of at least one electrically conductive terminal and the deposition of a reflective material in the pores of the porous alumina located to the right of said at least one electrically conductive terminal.

By a layer, a wall, a terminal or an element with the basis of a material A, this means a layer, a wall, a terminal or an element comprising this material A and optionally other materials, respectively.

By a parameter “substantially equal to/greater than/less than” a given value, this means that this parameter is equal to/greater than/less than the given value, plus or minus 20%, even 10%, of this value. By a parameter “substantially between” two given values, this means that this parameter is, as a minimum, equal to the lowest given value, plus or minus 20%, even 10%, of this value, and as a maximum, equal to the greatest given value, plus or minus 20%, even 10%, of this value.

It is specified that, in the scope of the present invention, the terms “on”, “surmounts”, “overhangs”, “covers”, “underlying” and their equivalents do not necessarily mean “in contact with”. Thus, for example, the transfer, the application or the deposition of a first layer on a second layer, does not compulsorily mean that the two layers are directly in contact with one another, but means that the first layer covers, at least partially, the second layer by being either directly in contact with it, or by being separated from it by at least one other layer or at least one other element.

An element is called “microscopic” when it has dimensions equal to or less than a few micrometres. Thus, a microLED, for example, has dimensions equal to or less than a few micrometres.

In the description below, the substrate, film or layer thicknesses are generally measured along directions perpendicular to the main extension plane of the substrate, of the film or of the layer.

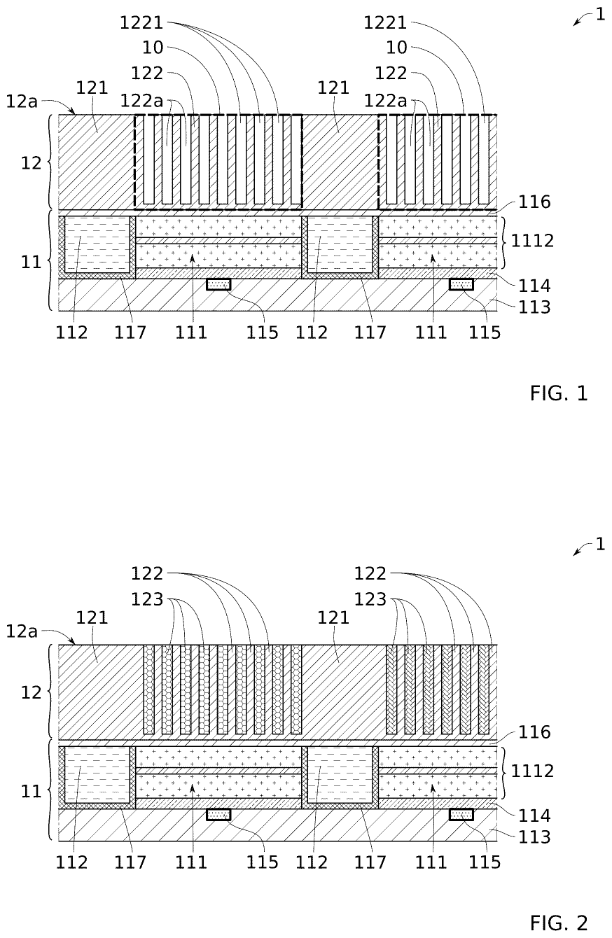

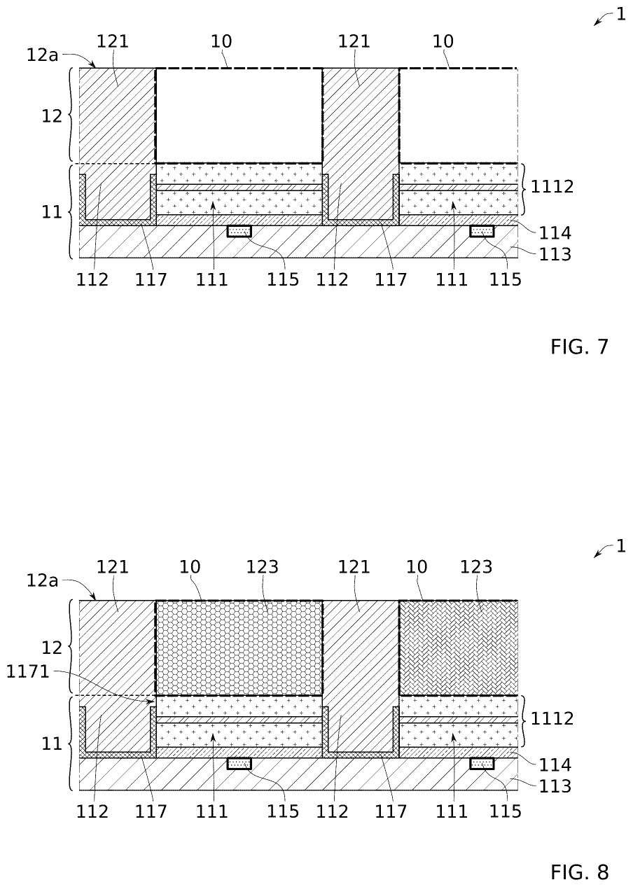

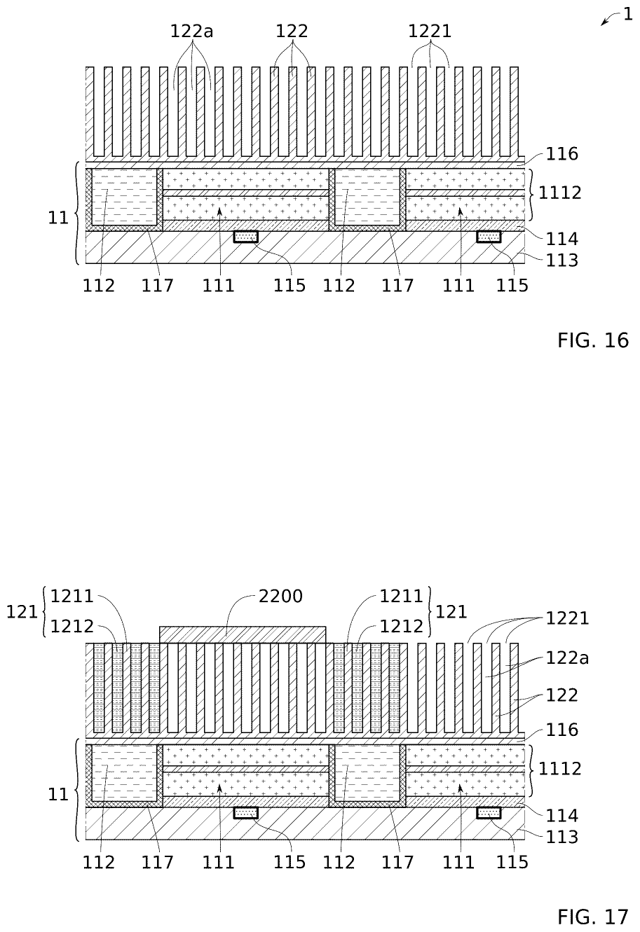

In reference to FIGS. 1 to 8 and 16 to 18, the first aspect of the invention relates to an optoelectronic device 1.

As these figures illustrate, the optoelectronic device 1 according to the first aspect of the invention comprises a stack 11 and a light confinement layer 12. More specifically, each of these figures illustrates a cross-sectional view of some of an optoelectronic device 1 according to an embodiment of the first aspect of the invention.

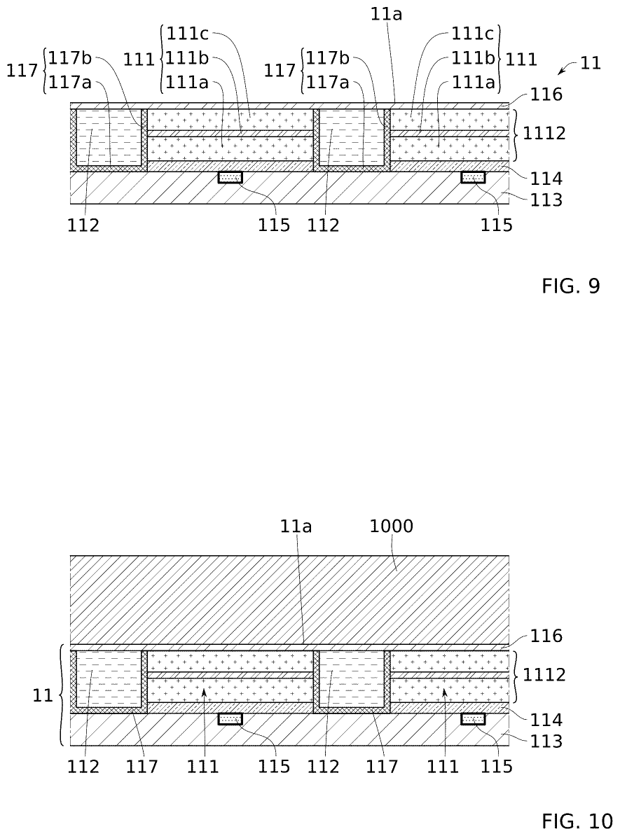

The invention also relates, according to a second aspect, to a method for manufacturing an optoelectronic device 1 according to the first aspect of the invention. Steps of different embodiments of this method are illustrated in FIGS. 9 to 15.

A third aspect of the invention relates to a display screen or a system for projecting at least one image comprising at least one optoelectronic device 1 according to the first aspect of the invention. The third aspect of the invention is not illustrated in the figures, but it is considered immediate for a person skilled in the art to know how the optoelectronic device 1 according to the first aspect of the invention is intended to integrate a display screen or an image projection system.

### The Stack 11

FIG. 9 illustrates an embodiment of the stack 11. It must be noted, in this case, that the illustration offered by FIG. 9 is structurally simplified. It is, however, deemed to be sufficient to illustrate the way in which the stack 11 is arranged relative to the other elements of each of the embodiments of the optoelectronic device 1. A person skilled in the art is deemed to know, through their general knowledge, at least one, even more, of the complex structures can take the stack 11.

In particular, in reference to this FIG. 9, the stack 11 comprises a plurality of light-emitting diodes 111 and a plurality of electrically conductive terminals 112. The light-emitting diodes 111 of the plurality are disposed at a distance from one another. The light-emitting diodes 111 of the plurality are preferably disposed on one same level of the optoelectronic device 1. The electrically conductive terminals 112 of the plurality are disposed between the light-emitting diodes 111 and extend through a bonding layer 114 which interfaces the P-N junction of each light-emitting diode 111 with an underlying substrate 113, preferably directly. The electrically conductive terminals 112 are preferably disposed on one same level of the optoelectronic device 1. Preferably, each electrically conductive terminal 112 is surrounded by light-emitting diodes 111, or conversely. Each terminal 112 and/or each light-emitting diode 111 is presented, for example, in the form of a substantially rectangular parallelepiped or that of a substantially straight cylinder.

The light-emitting diodes 111 and the electrically conductive terminals 112 can, for example, be disposed in a checkered pattern, without requiring that the light-emitting diodes 111 and the electrically conductive terminals 112 have the same dimensions, in particular transverse; the figures moreover illustrate, also in a non-limiting manner, terminals 112 having a dimension by width different from that of the light-emitting diodes 111. Moreover, it is noted, in this case, that the electrically conductive terminals 112 can be with the basis, even constituted of, a conductive metal such as copper or aluminium.

Still in reference to FIG. 9, each light-emitting diode 111 can be a light source for a subpixel. More specifically, each light-emitting diode 111 can comprise a semiconductive layer of the first type 111a, a light-emitting layer 111b, also called active layer, and a semiconductive layer of the second type 111c, which are stacked in this order. The light-emitting layer 111b is sandwiched between the semiconductive layer of the first type 111a and the semiconductive layer of the second type 111c. For example, the semiconductive layer of the first type 111a is a P-type semiconductor, the semiconductive layer of the second type 111c is an N-type semiconductor, and the light-emitting layer 112 is preferably a multiple quantum well (MQW) layer, but this description is not limited to this example. Alternatively, the semiconductive layer of the first type 111a can be an N-type semiconductor, and the semiconductive layer of the second type 111c can be a P-type semiconductor.

The light-emitting diodes 111 are typically adapted to emit blue light, i.e. a radiation, the wavelength of which is located in the range going substantially from 430 nm to 480 nm.

More specifically, the stack 11 can further comprise:
a. a carrier substrate 113,
b. an interfacing layer 114 extending over the carrier substrate 113 between the electrically conductive terminals 112, and
c. an emissive structure matrix 1112 extending, preferably directly, over the interfacing layer 114 between the electrically conductive terminals 112.

The carrier substrate 113 can comprise at least one application-specific integrated circuit (ASIC). The carrier substrate 113 can comprise at least one electrical connection terminal 115 between said integrated circuit and at least one, for example more, light-emitting diodes 111. The interfacing layer 114 extends between pairs of adjacent assemblies formed from the electrically conductive terminals 112 and side dielectric walls 117 (described in more detail below). The interfacing layer 114 can be constituted of at least one layer made of metallic materials and more typically, a stack of metallic material layers.

Each light-emitting diode 111 extends over the interfacing layer 114. Each electrical connection terminal 115 can form an electrical interconnecting via 115 between the carrier substrate 113 and the light-emitting diode 111 overhanging it, through the interfacing layer 114. The vias 115 are preferably located in an upper oxide layer (not represented in the figures) of the carrier substrate 113.

The carrier substrate can, for example, be of the CMOS type, and therefore, in this example, the vias 115 are preferably located above the last metallic levels of the CMOS.

The interfacing layer 114 preferably constitutes a conductive bonding interface between the carrier substrate 113 and the emissive structure matrix 1112. The interfacing layer 114 ensures the electrical conduction between the ASIC (located in the carrier substrate 113) and each light-emitting diode 111 via the vias 115.

The emissive structure matrix 1112 comprises at least the plurality of light-emitting diodes 111 and the plurality of electrically conductive terminals 112. This matrix 1112 preferably forms a level of each of the embodiments of the optoelectronic device 1 according to the first aspect of the invention.

At least one, preferably each, emissive structure 1112 comprises at least one light-emitting diode 111 and at least some of each of the adjacent electrically conductive terminals 112, isolated at least partially from one another electrically by the abovementioned dielectric wall 117.

The stack 11 can further comprise an electrode layer 116. The latter is preferably with the basis of a not only electrically conductive, but also transparent material, at least at the wavelengths emitted by the light-emitting diodes 111 that it covers. The electrode layer 116 is thus adapted to letting at least a significant part of the electromagnetic radiation emitted, or equivalently the light emitted, pass through the light-emitting diodes 111. The electrode layer 116 extends, if necessary continuously, between on the one hand, the light confinement layer 12 which will be described below (see, for example, FIG. 1) and on the other hand, the pluralities of light-emitting diodes 111 and of electrically conductive terminals 112.

The material forming the electrode layer 116 can be a conductive transparent material (CTM) which is a solid which does not absorb visible light (gap greater than 3 eV) and which has a good electrical conductivity, of indium tin oxide (ITO), aluminium- or gallium-doped zinc oxide, graphene, aluminium (preferably of a thickness substantially equal to 10 nm), aluminium-doped zinc oxide (AZO), or a combination of these materials. The thickness of the electrode layer 116 can be between 0.03 μm and 1 μm. It must be noted that the presence of an electrode layer 116 in the stack 11 is optional, in particular, insofar as a side electrical contact 1171 can be provided, which will be returned to below.

At least one, preferably each, emissive structure 1112 can further comprise at least one electrical isolation wall or dielectric wall 117. If necessary, the dielectric wall 117 ensures an electrical isolation between the elements that it separates, and in particular:
a. between at least one electrically conductive terminal 112 and the carrier substrate 113, and more specifically, between at least one electrically conductive terminal 112 and each adjacent interfacing layer 114, and/or
b. between at least one electrically conductive terminal 112 and at least one, preferably each, adjacent light-emitting diode 111, to avoid short-circuiting at least one p or n zone of the P-N junctions of the light-emitting diodes.

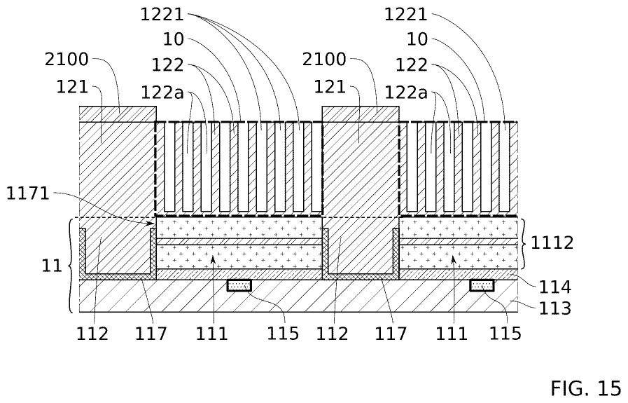

The electrical isolation ensures by the dielectric wall 117 can only be partial, in particular as soon as the optoelectronic device 1 does not comprise the abovementioned electrode layer 116. It is, indeed, at least preferable that, in this case, a side electrical contact 1171 (see, for example, FIG. 15) subsists between one, even each, electrically conductive terminal 112 of the plurality and the semiconductive layer of the second type 111c of at least one, preferably of each, of the adjacent light-emitting diodes 111.

More specifically, at least one, preferably each, emissive structure further comprises dielectric walls 117, first dielectric walls 117a of which extending between at least one, preferably each, conductive terminal 112 and the carrier substrate 113 and second dielectric walls 117b, called side, extending over at least some of the lateral sides of each conductive terminal 112, the first and second dielectric walls 117a and 177b preferably being attached to one another, such that each conductive terminal is electrically isolated over some of its perimeter.

### The Light Confinement Layer 12

In reference to FIGS. 1 to 8 and 18, the light confinement layer 12 extends over the stack 11. It comprises reflective walls 121. The latter are preferably located to the right of the electrically conductive terminals 112, and not to the right of the light-emitting diodes 111, so as to not oppose the passage of light emitted by the light-emitting diodes 111, and on the contrary, so as to reflect the light emitted by the light-emitting diodes 111 and thus reduce the optical crosstalk phenomena.

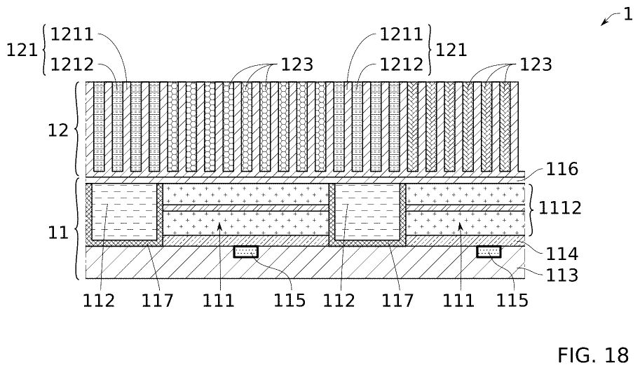

For example, at least one, potentially each, reflective wall 121 can be aluminium-based, even constituted of aluminium. Alternatively, it could be with the basis, even constituted of, any reflective material, in particular, the wavelengths emitted by the light-emitting diodes 111: it could, for example, be made of copper. However, one of the advantages of the present invention is to reduce the number of technological steps necessary for the manufacture of an optoelectronic device relative to the current methods; yet, as will be seen below, one of the advantageous features of certain embodiments of the invention consists of the presence of porous alumina 122 in the confinement layer 12, this alumina being generated on the stack 11 by local anodising of a prior aluminium deposition on the stack 11, said deposition also being able to form the reflective walls 121 outside of the anodised zones of the confinement layer 12. It is considered that at least some of the reflective walls 121 are not fully constituted of aluminium. According to an example, only some of an outer perimeter, in particular side, of the at least one, preferably of each, reflective wall 121 can be constituted of aluminium. Alternatively or complementarily, and as illustrated in FIG. 18, at least one, potentially each, reflective wall 121 can be with the basis of porous alumina 1211 and of a reflective or absorbent material 1212 located in the pores of the porous alumina 1211; this embodiment makes it possible to benefit from the highly anisotropic nature of the anodising of the aluminium in nanoporous alumina to obtain even more reflective and/or more absorbent walls 121, according to the nature of the material filling the pores.

As FIG. 1 illustrates, in particular, the reflective walls 121, whatever their constitution, define or delimit between them, spaces 10, or equivalently volumes, each located to the right of at least one light-emitting diode 111. More specifically, each space 10 can be located to the right of a pixel comprising, if necessary, several light-emitting diodes 111 or of a subpixel comprising, for example, one single light-emitting diode 111, and the reflective walls 121 defining said space 10 extend to the right of at least some, preferably of each, of the electrically conductive terminals 112 adjacent to said at least one light-emitting diode 111 to the right of which the space 10 is located.

It is in at least some of the spaces 10, potentially in each of these spaces 10, that the porous alumina 122 is formed.

The optoelectronic device 1 according to some of its different embodiments which are illustrated in FIGS. 1, 2, 5, 6, 17 and 18 is such that the light confinement layer 12 actually comprises the porous alumina 122 in at least some of said spaces 10, the porous alumina 122 having, in at least one space, preferably at least two spaces, even in each space, from among said at least some of said spaces, at least two open pores 1221 on a first face 12a of the confinement layer 12 which is located opposite the stack 11. It is noted that the embodiments which are illustrated in FIGS. 1, 2, 5, 6, 17 and 18 constitute all or some of the final products, opposed to intermediate products.

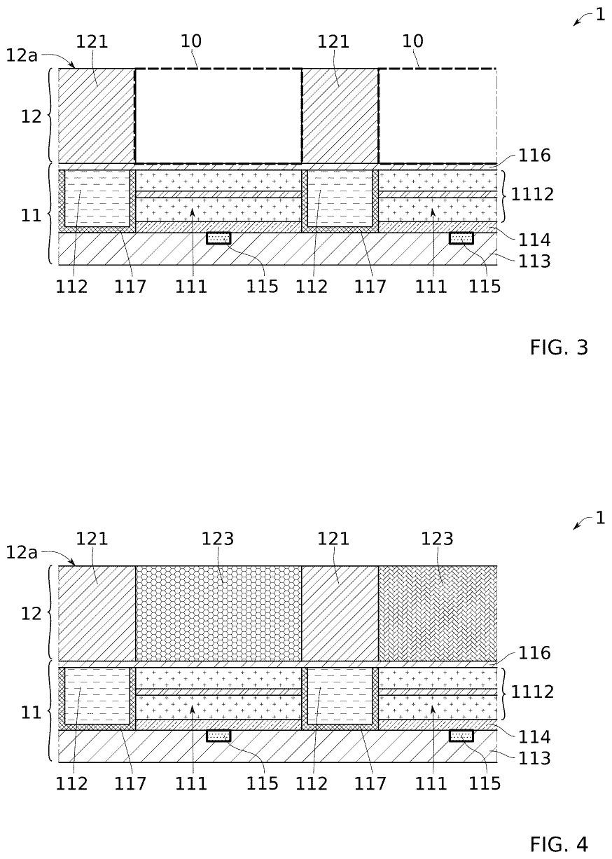

The embodiments of the first aspect of the invention which are illustrated in FIGS. 3, 4, 7 and 8 can also be considered as final products and cannot comprise porous alumina 122 to the right of some of said spaces 10. These embodiments are preferably manufactured from optoelectronic devices according to the first aspect of the invention such as illustrated in FIGS. 1, 3, 7, and 17, as intermediate products, the porous alumina 122 of these intermediate products having the advantage of being easy to etch to remove it totally or partially, locally or everywhere.

The pores 1221 of the porous alumina 122 located to the right of the spaces 10, whether they are those of the abovementioned final products or intermediate products, preferably have transverse dimensions of between 1 and 500 nm, and preferably between 50 and 400 nm. Alternatively or complementarily to the preceding preference, the pores 1221 of the porous alumina 122 preferably have a periodicity of between 200 and 700 nm. Moreover, the size of the pores is preferably greater than the dimension of the colour conversion particles that are sought to slide inside, so as to be able to have at least one colour conversion particle in each pore. The transverse dimension of the pores 1221 can therefore depend on the size of the particles of the light colour conversion material which are intended to be introduced there; the parameters of the anodising of the aluminium layer to form the porous alumina are preferably consequently defined.

The porous alumina 122 located, if necessary, to the right of the electrically conductive terminals 112 can have the same features as those stated above to qualify the porous alumina 122 located in at least some of the spaces 10.

Different materials are able to constitute said particles of the light colour conversion material. For example:
a. quantum dots,
b. J-aggregates,
c. phosphorescent (or fluorescent nanoparticles), and
d. perovskites,
   if necessary, put in a solution in a solvent or incorporated in a resin, are considered as particles made of a light colour conversion material. These particles can have different characteristic sizes from one another and a person skilled in the art is supposed to know how to configure the anodising through which the porous alumina 122 is formed to obtain open pores 1221 which make it possible to introduce at least one such particle there, preferably several such particles.
   It must be noted that the solvent in which said particles can be put in a solution can only be present at the time of the deposition of these particles in the pores 1221, as a subsequent drying step can advantageously make it possible to evaporate said solvent which is thus not found in the optoelectronic device 1 according to the first aspect of the invention.

The light colour conversion material 123 is preferably grafted to the internal walls of the pores 1221. The abovementioned solvent or resin can play an advantageous role in the formation of such grafts. But, more generally, the particles of the light colour conversion material 123 and/or the internal walls of the pores 1221 can be functionalised, before, even during, the deposition of the light colour conversion material 123 in the pores 1221 of the porous alumina 122, so as to obtain a grafting to one another, for example, by surface-OH hydrogen bonds, created, if necessary, by a treatment with an alkaline chemistry or by a dry plasma treatment or by adsorption of a ligand.

At least one, preferably each, open pore 1221 on the first face 12a of the confinement layer 12 which is located opposite the stack 11 preferably has a filling rate, made of the light colour conversion material, substantially equal to 30%. Reaching such a filling can be made easy by the abovementioned grafting.

### The Optoelectronic Device 1

The layer 12 called light confinement layer, as it is its main function, but, as has been seen above, it can also fulfil a colour conversion function; also, it would have been able to be called, for at least some of the embodiments of the first aspect of the invention, which are, in particular, illustrated in FIGS. 2, 4, 6, 8 and 18, “light confinement and conversion layer 12”.

The light-emitting diodes 111 can be configured to emit a light of a determined first wavelength, for example blue colour, along a direction substantially perpendicular to the first face 12a of the confinement layer 12.

Complementarily or alternatively, the light colour conversion material 123 can be specific to converting the light emitted at the first wavelength into a light having a second wavelength which is different from the first, for example, the first wavelength being located in blue, and the second wavelength being located in either from among green and red. According to an embodiment, the green light thus converted is of a wavelength located substantially in the range going from 510 nm to 570 nm. According to an embodiment, the red light thus converted is of a wavelength located substantially in the range going from 600 nm to 720 nm.

As FIGS. 1, 2, 5, 6 and 18 illustrate, the pores 1221 of the porous alumina 122 form channels 122a opening onto the first face 12a of the confinement layer 12. The channels 122a extend preferably mainly along a direction perpendicular to the first surface 12a of the confinement layer 12; they can more specifically extend over a distance Lp, taken in projection along a direction perpendicular to the first face 12a, strictly greater than half of a thickness E12 of the confinement layer 12. More specifically, the pores 1221 can extend substantially up to the stack 11, preferably without reaching it (except in the presence of the aluminium terminals above the conductive terminals, these aluminium terminals preventing the delamination of the structure), so as to limit any risk of delamination, to have a maximised internal wall surface, and thus maximise the abovementioned grafting, and consequently, the filling of the pores by the light colour conversion material 123. Thus, at least one, preferably each, pore 1221 can have a form factor defined by the transverse dimensions substantially of between 40 nm and 800 nm, and/or a longitudinal dimension substantially of between 500 nm and 10 μm, preferably substantially of between 1 μm and 5 μm.

The combination of said at least two pores 1221, even of said at least eight pores 1221, or of the at least one pore every 2×λ, where λ represents the wavelength to extract and at least four pores per space (1 μm pixel case), to the right of one same light-emitting diode 111, and a filling of the pores 1221 with a light colour conversion material 123 makes it possible to reach an increase of the conversion rate by synergy with the increase of the diffusion caused by the plurality of pores to the right of one same light-emitting diode 111, while benefiting from a decrease of the optical crosstalk phenomena by synergy with the reflective walls 121.

As already mentioned above, and as this will be the case of the final products illustrated in FIGS. 3, 4 and 8, the light confinement layer 12 can have no porous alumina 122 in at least one, potentially in more, of said spaces 10, the porous alumina 122 being all the same located in at least one of the spaces 10. Thus, at least one, preferably each, space 10 with no porous alumina 122 can be left ‘empty’, as illustrated in FIG. 3, or, on the contrary, be advantageously filled with a light colour conversion material 123, as illustrated in FIG. 4. The light colour conversion material 123 can, in the latter case, be chosen from among those mentioned above to fill the pores 1221.

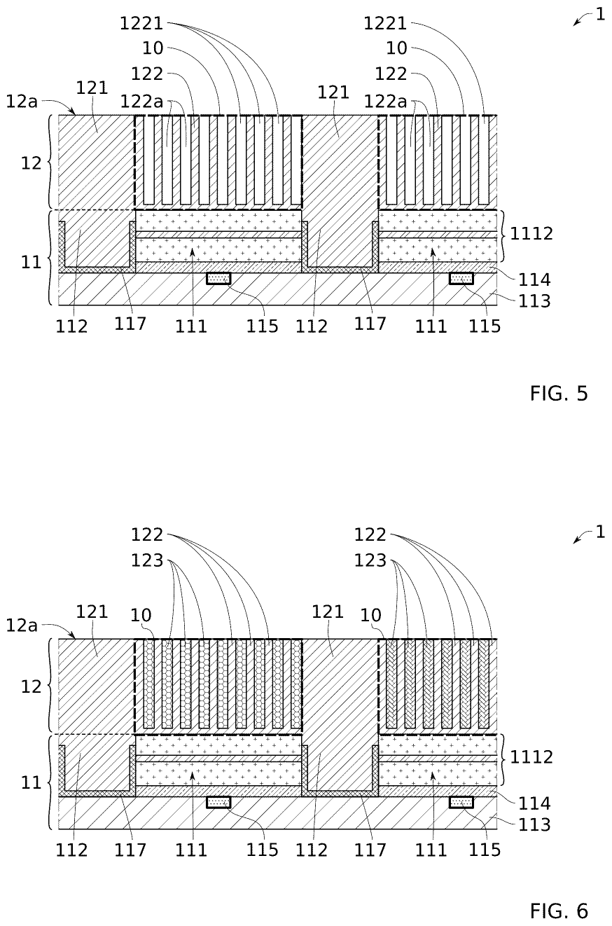

As seen above, at least one electrically conductive terminal 112 and the reflective wall 121 located to the right of said at least one electrically conductive terminal can be with the basis, even constituted of, aluminium; they can thus together form a bulk volume, in particular in the absence of the electrode layer 116, as is illustrated in FIGS. 5, 6, 7 and 8. The electrically conductive terminals 121 can thus be advantageously made of one same material as that with the basis of which the reflective walls 121 are constituted, which simplifies the device 1 and its manufacturing method, in particular, by avoiding a technological deposition step, for example, by electrodeposition, of electrically conductive terminals 121 with the basis of a metallic material other than aluminium, for example, copper-based.

### Manufacturing Method

Features linked to the implementation of the manufacturing method according to the second aspect of the invention of an embodiment of an optoelectronic device according to the first aspect of the invention have already been introduced above.

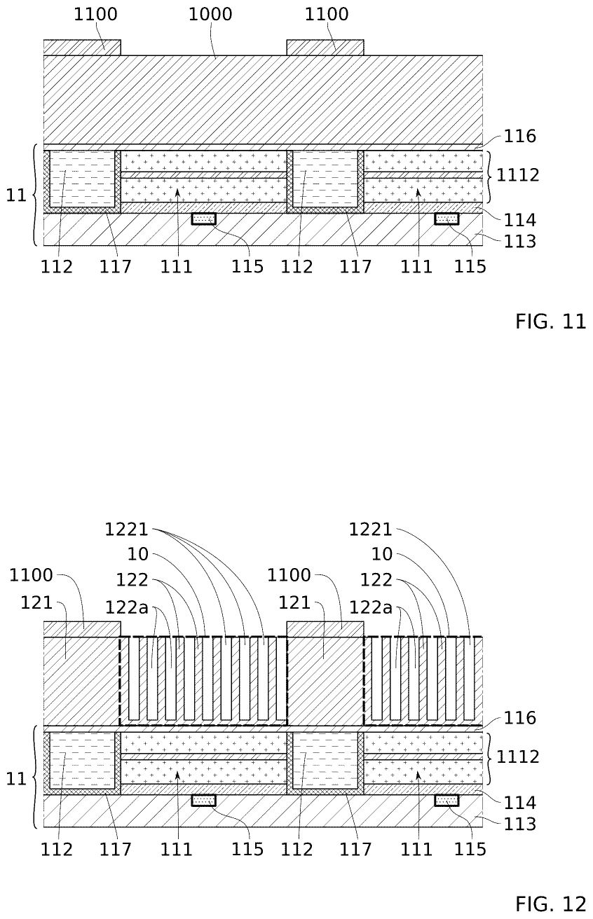

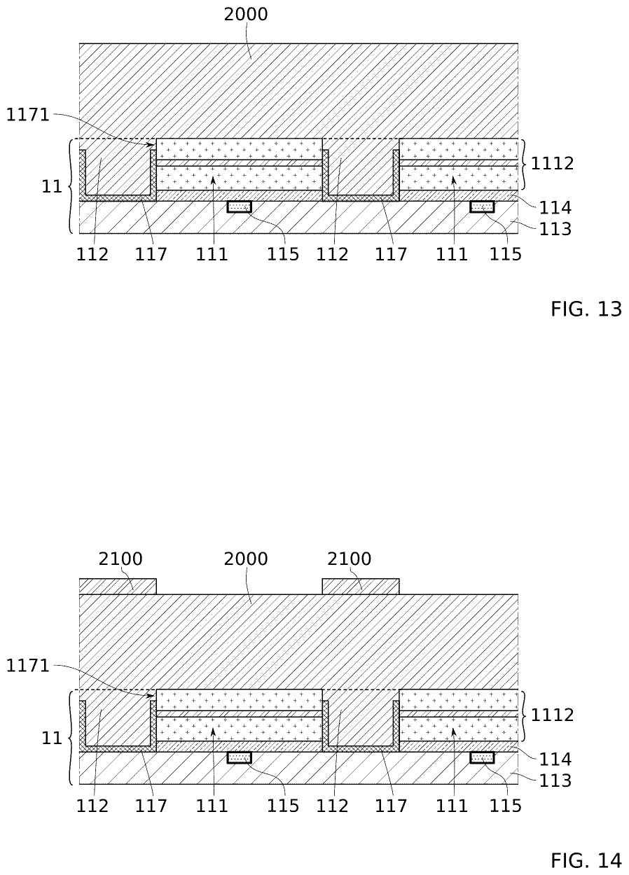

However, it is noted that the manufacturing method according to the second aspect of the invention comprises the following steps:
a. providing a stack 11, for example, such as illustrated in FIG. 9, comprising:
   i. a plurality of P-N junction light-emitting diodes 111 disposed at a distance from one another, and
   ii. a plurality of electrically conductive terminals 112 disposed between the light-emitting diodes, the electrically conductive terminals 112 being electrically isolated from at least one p or n zone of the P-N junctions of the light-emitting diodes 111, to avoid a short-circuit,
b. forming, on the stack 11, a light confinement layer 12 comprising reflective walls 121 defining between them, spaces 10, each located to the right of a light-emitting diode 111, by deposition of an aluminium-based layer 1000, 2000, as illustrated in FIGS. 10 and 13, on a main face 11a of the stack 11 through which the light-emitting diodes 111 are configured to emit, then
c. anodising the aluminium-based layer 1000, 2000 at least outside of zones located to the right of the conductive terminals 112 of the stack 11, to obtain, for example, the structures illustrated in FIGS. 11 and 12, and 14 and 15, respectively,
   the manufacturing method according to the second aspect of the invention being mainly such that the anodising is, as already stated above, configured such that the porous alumina 122 is formed in at least some of said spaces 10, by having, in at least one space, preferably at least two spaces, even in each space, from among said at least some of said spaces 10, at least two open pores 1221 on a first face 12a of the confinement layer 12 which is located opposite the stack 11.

A first implementation of the manufacturing method according to the second aspect of an embodiment of the optoelectronic device 1 according to the first aspect of the invention which is illustrated in FIG. 1 is described below as an illustration in reference to FIGS. 10 to 12. There, respectively the deposition of the aluminium layer 1000 of thickness E12 on the stack 11, and more specifically on the electrode layer 116 of the stack 11, then the localised anodising, thanks to masks 1100, zones of the aluminium layer 1000 which are located to the right of the light-emitting diodes 111 are observed, to reach an optoelectronic device such as illustrated in FIG. 12, to which it is sufficient to remove the masks 1100 to obtain the optoelectronic device such as illustrated in FIG. 1. The pores 1221 thus formed can then be filled with a light colour conversion material 123 such as detailed above to obtain the optoelectronic device such as illustrated in FIG. 2. It is noted that the anodising is done also partially under the mask. Consequently, the size of the mask is preferably less than the dimension of the nanoporous cavity; the greater the thickness to be anodised and, initially, the more this effect will be present.

A second implementation of the manufacturing method according to the second aspect of the invention of an embodiment of the optoelectronic device 1 according to the first aspect of the invention which is illustrated in FIG. 5 is described below as an illustration, in reference to FIGS. 13 to 15. There, respectively, the deposition of the electrically conductive terminals 112 between the light-emitting diodes 111 to finalise the stack 11, which has no electrode layer 116 is observed. Then, this deposition is extended to form the aluminium layer 2000 of thickness E12 on the stack 11, then the localised anodising, thanks to masks 2100, zone of the aluminium layer 2000 which are located to the right of the light-emitting diodes 111, to reach an optoelectronic device such as illustrated in FIG. 15, to which it is sufficient to remove the masks 2100 to obtain the optoelectronic device such as illustrated in FIG. 5. The pores 1221 thus formed can then be filled with a light colour conversion material 123 such as detailed above to obtain the optoelectronic device such as illustrated in FIG. 6.

It must be noted, echoing what has already been described above, that the abovementioned anodising step can further comprise the anodising, preferably simultaneous, of some of the aluminium-based layer 1000, 2000 which is located to the right of at least one electrically conductive terminal 112. The manufacturing method according to this example can subsequently further comprise the deposition of a reflective (or absorbent) material 1212 in the pores of the porous alumina 1211 located to the right of said at least one electrically conductive terminal 112.

The invention is not limited to the embodiments described above or to the implementations described above, and extends to all the embodiments covered and implementations covered by the invention.

1. An optoelectronic device, comprising:
a stack comprising:
a plurality of P-N junction light-emitting diodes disposed at a distance from one another, and
a plurality of electrically conductive terminals disposed between the light-emitting diodes, the electrically conductive terminals being electrically isolated from at least one p or n zone of the P-N junctions of the light-emitting diodes, and
a light confinement layer extending over the stack and comprising reflective walls defining between the walls, spaces each located to a right of at least one light-emitting diode,
the optoelectronic device being such that the light confinement layer further comprises the porous alumina in at least some of said spaces, the porous alumina having, in at least one space from among said at least some of said spaces, at least two open pores on a first face of the confinement layer, which is located opposite the stack,
wherein the at least one reflective wall is porous alumina-based and with the basis of a reflective material located in the pores of the porous alumina.

2. The optoelectronic device according to claim 1, wherein the pores of the porous alumina have transverse dimensions of between 1 and 500 nm.

3. The optoelectronic device according to claim 1, wherein the pores of the porous alumina have a periodicity of between 200 and 700 nm.

4. The optoelectronic device according to claim 1, wherein the porous alumina has, in at least one space, from among said at least some of said spaces, at least eight open pores on the first face of the confinement layer, which is located opposite the stack.

5. The optoelectronic device according to claim 1, wherein at least one open pore on the first face of the confinement layer that is located opposite the stack has a filling rate, made of the light color conversion material, substantially equal to 30%.

6. The optoelectronic device according to claim 1, wherein the pores of the porous alumina form channels opening onto the first face of the confinement layer.

7. The optoelectronic device according to claim 1, wherein the pores of the porous alumina form channels extending mainly along a direction perpendicular to the first surface of the confinement layer.

8. The optoelectronic device according to claim 1, wherein at least some of the pores have a dimension by length, taken in projection along a direction perpendicular to the first face, at most equal to a thickness of the aluminium-based layer.

9. The optoelectronic device according to claim 1, wherein the pores extend substantially up to the stack.

10. The optoelectronic device according to claim 1, wherein at least one pore has a form factor defined by transverse dimensions substantially between 40 nm and 800 nm, and/or a longitudinal dimension substantially of between 500 nm and 10 μm.

11. The optoelectronic device according to claim 1, wherein the open pores on the first face of the confinement layer occupy a surface substantially equal to 30% of the total surface of the confinement layer and/or the open pores above at least one light-emitting diode which are adjacent to one another can be distant in pairs, by their centers, by a distance substantially equal to a wavelength of the light emitted by the underlying light-emitting diode, the wavelength belonging to the blue light spectrum between 380 and 450 nm.

12. The optoelectronic device according to claim 1, wherein the stack further comprises:
a carrier substrate, and
an emissive structure matrix extending over the carrier substrate,
the emissive structure matrix comprising the plurality of light-emitting diodes that extend over the carrier substrate through an interfacing layer and the plurality of electrically conductive terminals that extends over the carrier substrate through an electrical isolation wall.

13. The optoelectronic device according to claim 1, wherein the at least one reflective wall is aluminium-based.

14. The optoelectronic device according to claim 13, wherein at least one electrically conductive terminal is aluminium-based, and
wherein said at least one electrically conductive terminal and the reflective wall located to a right of said at least one electrically conductive terminal form a bulk volume.

15. The optoelectronic device according to claim 1, further comprising a light color conversion material located in the pores of the porous alumina located to a right of at least one light-emitting diode.

16. The optoelectronic device according to claim 15, wherein the light color conversion material is grafted to the internal walls of the pores.

17. The optoelectronic device according to claim 15, wherein the light confinement layer has no porous alumina in at least one of said spaces.

18. A method for manufacturing an optoelectronic device, the method comprising:
providing a stack comprising a plurality of P-N junction light-emitting diodes disposed at a distance from one another, and a plurality of electrically conductive terminals disposed between the light-emitting diodes, the electrically conductive terminals being electrically isolated from at least one p or n zone of the P-N junctions of the light-emitting diodes,
forming, on the stack, a light confinement layer comprising reflective walls defining between the walls, spaces, each located to the right of a light-emitting diode, by
deposition of an aluminium-based layer on a main face of the stack through which the light-emitting diodes are configured to emit, and
anodising the aluminium-based layer at least outside of zones located to the right of the conductive terminals of the stack,
the anodising being configured such that the porous alumina is formed in at least some of said spaces, by having, in at least one space from among said at least some of said spaces, at least two open pores on a first face of the confinement layer, which is located opposite the stack, and
wherein the anodising step further comprises anodising of some of the aluminium-based layer that is located to a right of at least one electrically conductive terminal, and further comprises the deposition of a reflective material in the pores of the porous alumina located to a right of said at least one electrically conductive terminal.

19. The manufacturing method according to claim 18, wherein the step of anodising the aluminium-based layer is configured such that the porous alumina form channels opening through the open pores on the first face of the confinement layer, and such that at least one channel has transverse dimensions substantially of between 40 nm and 800 nm, and/or a longitudinal dimension substantially of between 500 nm and 10 μm.

20. A display screen or system for projecting at least one image comprising at least one optoelectronic device according to claim 1.
